(19) United States
(12) Patent Application Publication
(10) Pub. No.: US 2014/0026944 A1
(43) Pub. Date: Jan. 30, 2014

(54) ABSORBER TUBE FOR A TROUGH COLLECTOR

(71) Applicant: Andrea Pedretti, Bellinzona (CH)

(72) Inventor: Andrea Pedretti, Bellinzona (CH)

(73) Assignee: Airlight Energy IP SA, Biasca (CH)

(21) Appl. No.: 13/878,936

(22) PCT Filed: Oct. 24, 2011
(86) PCT No.: PCT/CH2011/000258

§ 371 Date: May 17, 2013

(30) Foreign Application Priority Data
Oct. 24, 2010 (CH) 1744/10
Oct. 24, 2010 (CH) 1745/10
Oct. 24, 2010 (CH) 1746/10
Oct. 25, 2010 (CH) 1774/10
Oct. 25, 2010 (CH) 1775/10
Oct. 25, 2010 (CH) 1776/10

(51) Int. Cl. F24J 2/14; H01L 31/058; F24J 2/24

(52) U.S. Cl. CPC F24J 2/14; F24J 2/24; H01L 31/058
USPC 136/248; 126/651; 126/694

(57) ABSTRACT

The invention relates to a trough collector having a focal area and an absorber tube arranged in the focal area, said absorber tube having an insulating area that extends from its outer surface to the inside, enclosing preferably a transport channel that runs through the absorber tube along its length and carries a heat-transporting medium, and is penetrated by at least one thermal opening that extends radially from the outside through the insulating area to the transport channel. According to the invention, the at least one thermal opening comprises a constriction for radiation passing through it, the focal area being located in the constriction.

The present invention relates to a trough collector having a focal region and an absorber tube disposed in the focal region.

Trough collectors of the said type are used, inter alia, in solar power plants.

So far, on account of the disadvantages of photovoltaic methods which have not yet been surmounted, it has not been possible to generate solar power using this technology in a manner that approximately covers costs. Solar thermal power plants, on the other hand, have already been producing power on an industrial scale for some time at prices which, compared to photovoltaic methods, are close to the commercial prices now usual for power produced in the conventional manner.

In solar thermal power plants, the sun's radiation is reflected by collectors with the aid of the concentrator and is specifically focussed onto a location at which high temperatures are thereby produced. The concentrated heat can be removed and used for operating thermal machines such as turbines which in turn drive power-generating generators.

Three basic forms of solar thermal power plants are in use today: dish Stirling systems, solar tower power plant systems and parabolic trough systems.

Dish Stirling systems as small units in the range of up to 50 kW per module have not been generally accepted. Solar tower power plant systems have a central absorber mounted in an elevated manner (on the “tower”) for the hundreds to thousands of individual mirrors, with sunlight reflected to them, with the result that the Sun's radiation energy is concentrated via the many mirrors or concentrators in the absorber and temperatures up to 1300° C. are thus achieved, which is favourable for the efficiency of the downstream thermal machines (usually a steam or fluid turbine power plant for power generation). The “Solar two” plant in California has a power of several megawatts. The PS20 installation in Spain has a power of 20 MW. Solar tower power plants have also not been widely used so far (despite the advantageously attainable high temperatures).

Parabolic trough power plants are widely used and have a large number of collectors which have long concentrators having small transverse dimensions and therefore do not have a focal point but a focal line. These line concentrators today have a length of 20 m to 150 m. An absorber line for the concentrated heat (up to around 500° C.) runs in the focal line, which transports this to the power plant. Thermal oil or superheated water can be considered as transport medium.

Conventional absorber tubes are manufactured with a complex and expensive structure in order to minimize the heat losses as far as possible. Since the heat-transporting medium circulates in the tube interior, the solar radiation concentrated by the concentrator firstly heats the tube and this then heats the medium with the consequence that the absorber tube which is necessarily hot at around 500° C., emits heat according to its temperature. The emission of heat via the line network for the heat-transporting medium can reach 100 W/m, the line length in a large installation can reach up to 100 km, so that the heat losses via the line network are of considerable importance for the overall efficiency of the power plant as is the fraction of heat losses attributable to the absorber tubes. WO 2010/078 668 discloses an externally insulated absorber tube, whose slit opening given by the use in a trough collector is optimized with regard to the heat losses.

Depending on the design of the absorber tube, the term “thermal opening” can designate a physical opening in the external insulation of an absorber tube according to the aforesaid publication. In other designs however, the term “thermal opening” also comprises a physically closed region which is designed for the passage of heat of the concentrated solar radiation, where back-radiation of heat can be reduced, for example, by suitable coatings at the location of the thermal irradiation. Such constructions are known to the person skilled in the art. Nevertheless, it is necessarily the case that at the location of the thermal opening, ultimately good insulation cannot be achieved, that is the corresponding relevant heat losses must be accepted.

It is pointed out, that the term “thermal opening” is also used here for absorber arrangements, which are equipped with photovoltaic cells, producing electric current if irradiated. Such absorber arrangements or absorber tubes respectively are also embodiments according to the present invention. Absorber tubes according to the present invention being equipped with attachments for photovoltaic cells have them located at the place of the thermal opening. With other words, in this case the thermal openings are formed as mounts for the photovoltaic cells. In such a case, the isolation may be omitted. Also, a transport channel for the heat transporting fluid may be omitted.

The 9 SEGS trough power plants in Southern California together produce a power of about 350 MW. The “Nevada Solar One” power plant which went onto the grid in 2007 has trough collectors with 182,400 curved mirrors which are arranged on an area of 140 hectares and produce 65 MW. Andasol 3 in Spain has been under construction since September 2009, and should start operation in 2011 so that the Andasol 1 to 3 plants have a maximum power of 50 MW.

A peak efficiency of about 20% and an yearly average efficiency of around 15% is expected for the total plant (Andasol 1 to 3).

As mentioned, an essential parameter for the efficiency of a solar power plant is the temperature of the transport medium heated by the collectors, via which the heat obtained is removed from the collector and is used, for example, for conversion into power; with higher temperature, a higher efficiency can be achieved in the conversion. The temperature attainable in the transport medium in turn depends on the concentration of reflected solar radiation by the concentrator. A concentration of 50 means that in the focal region of the concentrator, an energy density per m² is achieved which corresponds to 50 times the energy emitted by the sun onto one m² of the Earth's surface.

The theoretically maximum possible concentration depends on the Earth—Sun geometry, i.e. on the aperture angle of the solar disk observed from the Earth. It follows from this aperture angle of 0.27° that theoretically maximum possible concentration factor for trough collectors is 213.

Even with mirrors which are very complexly manufactured and therefore (too) expensive for industrial use, which are very well approximated to a parabola in cross-section and therefore produce a focal line region having the smallest diameter, it is not possible today to even approximately reach this maximum concentration of 213. A reliably attainable concentration of about 50 to 60 is, however, realistic and already allows the aforesaid temperatures of about 500° C. in the absorber tube of a parabolic trough power plant.

In order to approximate the parabolic shape of a trough collector as far as possible with reasonable costs, the applicant proposed a trough collector in WO 2010/037 243 which comprises a pressure cell having a flexible concentrator spanned in the pressure cell. In this case, the concentrator is differently curved in different regions and thus comes very close to the desired parabolic shape. This enables a temperature of about 500° C. to be reached in the absorber tube at reasonable costs for the concentrator.

At this place, reference is made to WO 2010/099516 disclosing an absorber tube having a passage with a restricting through its isolation. The restriction is located at the inner side of the isolation, whereby the passage is made as a compound parabolic concentrator (CPC). Driven by optical reasons, in such an arrangement the focal region lies at the outside of the passage, where the passage has the greatest width. The CPC has the purpose to continuously reflect the rays unavoidably hitting the walls of the passage throughout the whole passage such that the rays indeed reach the interior of the absorber tube. Such an arrangement is disadvantageous, because the mirrors of the CPC must be continuously cooled, involving a remarkable constructive effort.

It is the object of the present invention to provide a trough collector for the production of heat even on an industrial scale which has the highest possible efficiency.

This object is achieved on the one hand by a solar collector having the features of claim 1 or an absorber tube having the features of claim 9.

Since the thermal opening for radiation passing through has a constriction at the position of the focal region, the back-radiation of heat from the absorber tube is minimised which increases the amount of heat that can be removed and thus increases the efficiency of the trough collector.

Since the focal region lies in the constriction, this has the minimum possible extension since the path of the concentrated radiation entering into the absorber tube has its minimal extension in the focal region.

Since in preferred embodiments the thermal opening expands from the constriction, the concentrated radiation can diverge again after the focal region and thus reach the transport channel and there heat the heat-transporting medium.

The formulated object is also achieved on the other hand by a solar collector having the features of claim 19 or an absorber tube having the features of claim 21.

Since a plurality of thermal openings are disposed adjacent (side by side) to one another, running over the length of the absorber tube, each section of a linear concentrator can be assigned a thermal opening. By using a plurality of sections, not only the geometry of the trough collector as such can be optimised (for a better approximation to the parabolic shape, see WO 2010/037 243) but according to the invention, the width of the thermal opening in the absorber tube can be additionally reduced to such an extent that the total of the widths of all the thermal openings in the division according to the invention is smaller than the width of a single thermal opening which absorbs the concentrated radiation of all the concentrator sections over its total width. This is because the concentration of solar radiation in a trough-shaped linear concentrator decreases relatively with increasing width, several sections have a smaller width and therefore the concentration of a thermal opening assigned to only one section is higher over its total (and according to the less wide section: also smaller) width. With the division of a conventional single thermal opening running along the absorber tube according to the invention into a plurality of longitudinally running thermal openings, therefore either this same amount of heat can be achieved with an overall smaller area of the thermal openings or a higher amount of heat absorbed by the thermal openings can be achieved with overall the same area.

With an overall smaller area, the thermal irradiation of the absorber tube is reduced accordingly, with the result that its efficiency is increased.

Naturally, instead of the longitudinally continuous openings, a plurality of rows of individual thermal openings running along the absorber tube can also be provided, as is described in detail further below. As a result, the overall area of the thermal openings is additionally reduced in an advantageous manner.

It is understood that the configuration of the thermal openings with a constriction according to the invention is not necessarily related to the arrangement of a plurality of thermal openings on the absorber tube. Both arrangements can certainly be advantageously combined, i.e. a plurality of thermal openings provided side by side, which at least partially comprise the constrictions according to the invention. The arrangements can, however, also be implemented independently of one another, e.g. a plurality of openings side by side without constrictions or a single, conventional thermal opening configured as a longitudinal slit on the absorber tube, which is provided with a constriction.

Preferred embodiments of the present invention exhibit the features of the dependent claims.

The invention is explained in detail hereinafter with reference to the figures.

In the figures:

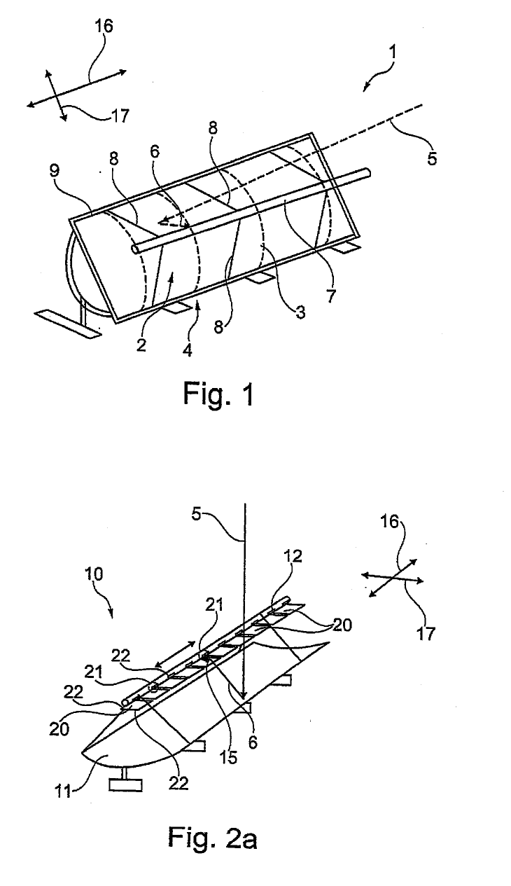

FIG. 1 shows a conventional trough collector,

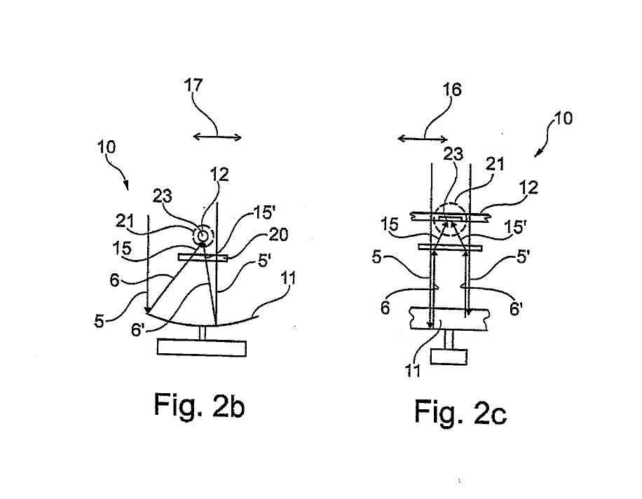

FIG. 2a shows a trough collector with a second concentrator arrangement,

FIG. 2b shows a view in a cross-sectional plane of the trough collector from FIG. 2a,

FIG. 2c shows a view in a longitudinal plane of the trough collector from FIG. 2c

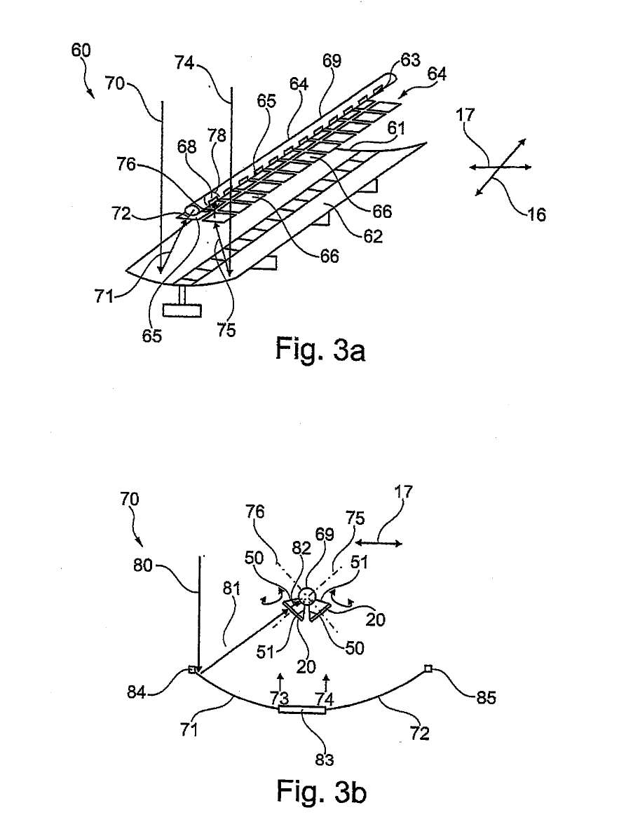

FIG. 3a shows a trough collector with a second concentrator arrangement according to a further embodiment

FIG. 3b shows a section in a cross-sectional plane of the trough collector from FIG. 3b,

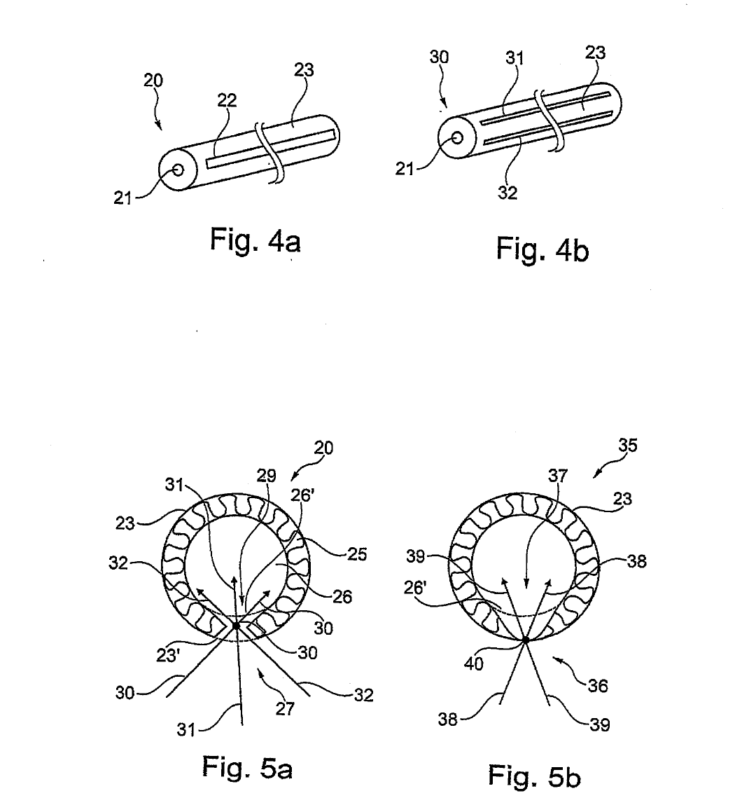

FIG. 4 shows a view of an absorber tube with its thermal opening,

FIG. 5a shows a cross-section through a first embodiment of the absorber tube from FIG. 4,

FIG. 5b shows a cross-section through a second embodiment of the absorber tube from FIG. 4,

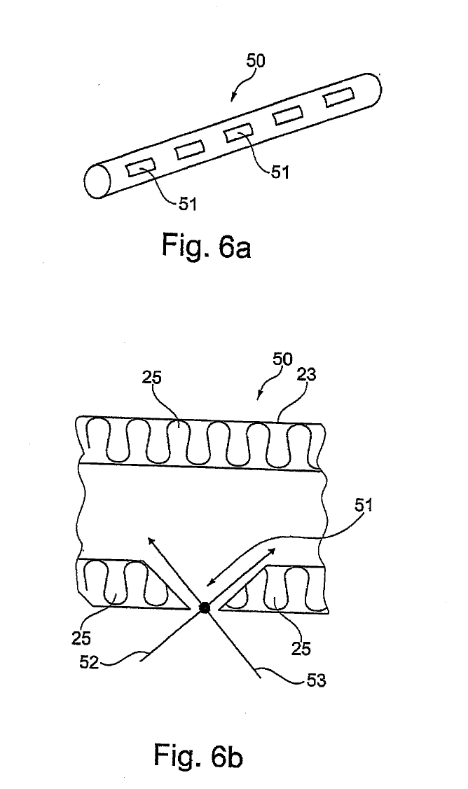

FIG. 6a shows a view of an absorber tube according to a further embodiment

FIG. 6b shows a longitudinal section over a partial region of the absorber tube from FIG. 6a,

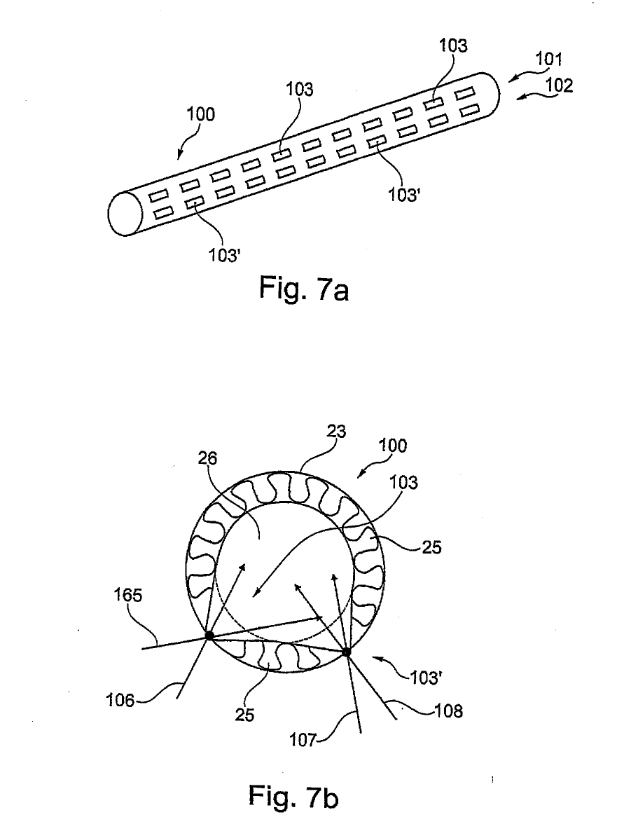

FIG. 7a shows a view of an absorber tube according to yet another embodiment and

FIG. 7b shows a longitudinal section over a partial area of the absorber tube from FIG. 7a.

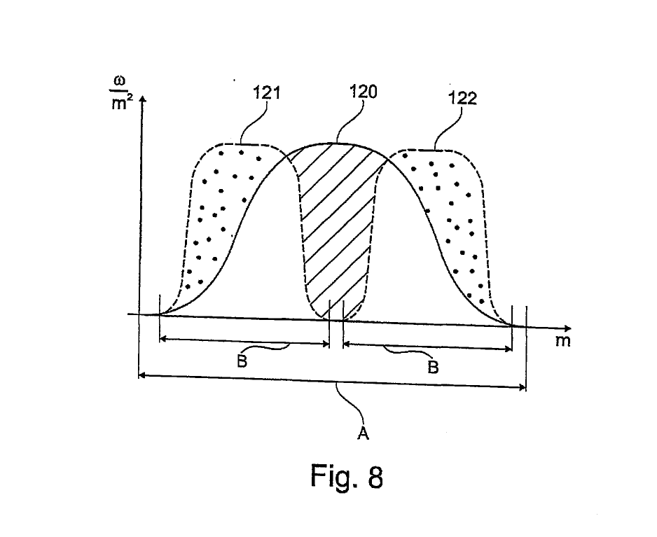

FIG. 8 shows a diagram with regard to the difference of received power depending on one row or more than one row of thermal openings (or photovoltaic cells respectively) provided on an absorber arrangement.

FIG. 1 shows a trough collector 1 of conventional type comprising a pressure cell 2 which has the form of a cushion and which is formed by an upper flexible membrane 3 and a lower flexible membrane 4 which is covered in the figure.

The membrane 3 is transparent for solar rays 5 which are incident inside the pressure cell 2 on a concentrator membrane (concentrator 10, FIG. 2a) and are reflected by these as rays 6 to an absorber tube 7 in which a heat-transporting medium is circulating, which removes heat concentrated by the collector. The absorber tube 7 is held by supports 8 in the focal line region of the concentrator membrane (concentrator 10, FIG. 2a).

The pressure cell 2 is clamped in a frame 9 which in turn is tiltably mounted in a known manner on a framework according to the daily position of the sun.

Such solar collectors are described, for example in WO 2010/037243 and WO 2008/037108. These documents are included by reference expressly in the present description.

In summary, it can be noted that the radiation path of a trough collector according to FIG. 1 comprises a focal line region, where the absorber tube is disposed at the location of the focal line region.

Although the present invention is preferably used in a solar collector of this type configured as a trough collector, i.e. comprising a pressure cell and a concentrator membrane spanned in the pressure cell, it is in no way restricted to this but can also be used, for example, in trough collectors whose concentrators are configured as non-flexible mirrors. Collectors having non-flexible mirrors are used, for example, in the afore-mentioned power plants.

In the figures described hereinafter, in each case the parts of the trough collector not relevant for understanding the invention are omitted, where it is mentioned again here that these omitted parts are configured according to the prior art described above (collectors having a pressure cell or those having non-flexible mirrors) and can easily be determined by the person skilled in the art for the specific case of application.

FIG. 2a shows another embodiment of a trough collector which has not been known to date. A collector 10 configured in principle like the collector 1 from FIG. 1 has a concentrator 11 and an absorber tube 12 mounted on supports 8. Solar rays 5 are incident on the concentrator 11 and are reflected by this as rays 6. Due to the specific configuration of the concentrator 11, a first radiation path is obtained for reflected radiation which is represented by the rays 6.

Since it is only curved in one direction, the concentrator 11 is a linear concentrator with the advantage that it can be manufactured more simply and additionally with a large area compared with the parabolic concentrators curved in two directions without prohibitive constructive boundary conditions being obtained for the frame structure and the alignment required continuously over the day according to the position of the sun.

For the orientation in the figure, the arrow 16 shows the longitudinal direction, the arrow 17 the transverse direction. Accordingly the concentrator 11 is curved in the transverse direction 17 and not in the longitudinal direction 16.

The radiation path of the concentrator 11 necessarily has a focal line region since on the one hand, as a result of the aperture angle of the sun, its radiation 5 is not incident in a parallel manner, therefore concentration into a geometrically precise focal region is by no means possible and additionally because a precise parabolic curvature of the concentrator is not feasible at reasonable cost for a focal line approximated theoretically as far as possible.

The concentrator 11 is part of a first concentrator arrangement of the collector 10 which is formed here from the pressure cell (omitted here as mentioned above to avoid burdening the figure), units for maintaining and controlling the pressure and the frame in which the concentrator 11 is spanned. As already mentioned, the omitted elements are familiar to the person skilled in the art.

In the figure, plate-shaped optical elements 20 transparent for concentrated radiation are disposed in the first radiation path of the concentrator 11 (and therefore in the radiation path of the first concentrator arrangement) so that the radiation path runs through these. These optical elements 20 refract the radiation 6 incident on them (reflected by the concentrator 11) in such a manner that after the optical elements 20 the radiation 6 is concentrated as radiation 15 in a focal point region. In other words, the second radiation path of each of the optical elements 20 represented by the radiation 15 has a focal point region 21. A number of optical elements 20 corresponding to the length of the solar collector are shown in the figure and their focal point regions are depicted, for example, at two optical elements 20.

The optical elements 20 are part of a second concentrator arrangement which is disposed in the first radiation path in front of the focal line region. Here, for example, supports 22 which are fixed on the absorber tube 12 and on which the optical elements 20 are held in position, belong to the second concentrator arrangement.

The absorber element configured here as absorber tube 12 is located at the location of the focal point regions 21 and has a number, at least one, of thermal openings 23 for passage of the concentrated radiation 15 into the interior of the absorber tube 12. The thermal openings 23 are disposed consecutively (in a row) over the length of the absorber tube.

FIG. 2b shows a section in the transverse direction (arrow 17) through the collector 10 from FIG. 2a with a view of the radiation path projected into this cross-sectional plane, or of the first and second radiation path of the two concentrator arrangements. As mentioned above, all elements of the trough collector 10 not essential for understanding the invention are familiar to the person skilled in the art and are omitted to avoid burdening the figure.

In particular, it is apparent that the first radiation path of the first concentrator arrangement (concentrator 11), shown here by the two reflected rays 6, 6′ converges towards a focal line region 21 at the location of the absorber tube 12. The radiation 6 passes through the optical element 20, where its second radiation path, shown here by the two rays 15, 15′, converges towards the focal point region 21.

The concentration of the first concentration arrangement is accomplished in the transverse direction (arrow 17).

In the preferred embodiment shown the focal point regions 21 of the optical elements 20 lie in the focal line region of the concentrator 11, i.e. in the focal line region of the first concentrator arrangement. From this it follows for the view onto the cross-sectional plane shown in FIG. 2b (but not in the longitudinal direction, see FIG. 2c hereinafter) that the reflected radiation 6 is not refracted by the optical element 20, i.e. lies substantially in a straight line. This is substantially because when a ray 6, 6′ passes through the optical element 20, a slight offset of the radiation path 15, 15′ compared with the path 6, 6′ can occur but this is not relevant here.

Again the non-essential elements, here including the supports 22 (FIG. 2a) for the optical elements 20 are omitted to avoid burdening the figure.

FIG. 2c shows a section through the collector 10 from FIG. 2a in the longitudinal direction (arrow 16) with a view of the radiation path projected into the longitudinal plane or of the first and second radiation path of the first and second concentrator arrangement. However, only a part of the longitudinal section over the length of one of the optical elements 20 is shown.

With an assumed viewing direction from right to left (FIG. 2b), FIG. 2c shows the view onto the left half of the concentrator 11 (FIG. 2b).

In particular, it is apparent that the first radiation path of the first concentrator arrangement (concentrator 11), shown here by the reflected rays 6, 6′, runs towards a focal line region at the location of the absorber tube 23. The radiation 6 to 6′ passes through the optical elements 20, is refracted by these in the longitudinal direction 16, where the second radiation path of the optical elements 20 (shown by the rays 15, 15′) converges towards respectively one focal line region 21.

The concentration of the second concentration arrangement is accomplished in the longitudinal direction (arrow 16).

It is found that the second concentrator arrangement comprises at least one optical element 20 with a second radiation path, where at least one focal point region 21 is produced by the at least one optical element 20. At this point it should be noted that the arrangement according to the invention can be implemented for small or very small applications with only one optical element 20 or for industrial application in collectors having very large dimensions with dozens or hundreds of optical elements 20.

It further follows from FIGS. 2b and 2c that in the embodiment shown the optical element 20 is configured as a linear concentrator, whose direction of concentration runs transversely or perpendicularly to the direction of concentration of the linear concentrator of the first concentrator arrangement.

It therefore further follows that the optically active surfaces (at which the refraction of the light rays is produced) of the optical elements 20 are aligned with respect to the first radiation path of the first concentrator arrangement (here the concentrator 11) in such a manner that the path of each individual ray projected onto a plane perpendicular to the focal line region (shown in FIG. 2b) is a straight line but in a plane (shown in FIG. 2c) lying in the focal line region, is refracted towards the focal point region 21.

The optical elements preferably have a Fresnel structure which allows these to be configured with a plate-shaped body, as shown in FIGS. 2a to 2c. For example, the underside of the plate-shaped body can be configured to be flat and the upper side structured with parallel Fresnel steps, where the steps in the transverse direction 17 run parallel to one another so that the focal point region lies above the centre of the plate-shaped body.

The design of such a Fresnel lens 30 can easily be made by the person skilled in the art in each specific case. Alternatively, each optical element 20 can also be configured as a collimating lens which extends transversely below the absorber tube 12 and produces the refraction according to FIGS. 2b and 2c. Optical elements 20 configured in such a manner can, for example, be produced by casting, in which a metal mould is produced and a suitable transparent plastic material (or also glass) is cast.

In summary, it can be noted that the radiation path of a trough collector according to FIGS. 2a to 2c has a number of focal point regions disposed in a line, where the absorber tube is disposed at the location of the focal point regions.

FIG. 3a shows a collector 60 whose first concentrator arrangement comprises a plurality of concentrator sections 61, 62 running adjacent to one another and longitudinally. At this point it should be noted that the first concentrator arrangement can have not only two but, for example, four, six, eight or more such concentrator sections. A concentrator arrangement with six sections is described in WO 2010/037243.

A row 63, 64 of optical elements 65, 66 is assigned to each concentrator section 61, 62, where in turn each optical element 65, 66 is assigned its own thermal opening 67, 68 in the absorber tube 69. Again, to avoid burdening the figure, the supports for the optical elements 65, 66 and other elements not essential for understanding the invention are omitted.

This arrangement has the advantage that the transverse extension (direction 17) of the individual concentrator sections 61, 62 is smaller than would be the case with a single concentrator so that smaller focal point regions can be achieved (aperture angle of the sun) compared with a broader concentrator. This in turn leads to smaller thermal openings 67, 68 whose entire area is smaller than the area of the thermal openings with only one but significantly wider concentrator.

Naturally all the optical elements 65, 66 according to the invention are disposed tiltably on the absorber tube 69 as is shown for example in FIGS. 4 to 5b. Likewise the optical elements 65, 66 are also configured, for example, as Fresnel lenses as described above.

A correspondingly configured absorber tube therefore has not only one but two or more rows running over its length, each consisting of thermal openings 67, 68 disposed consecutively (FIG. 7 shows an example of two rows).

FIG. 3b shows a slightly modified collector 70 compared with FIG. 3a, also having two concentrator sections 71, 72 and two rows 73, 74 of optical elements 20 (at this point, it can be added that in general more than two concentrator sections can be provided instead of the two sections specified in the present case as an example in the figures, as is disclosed for example in the aforesaid WO 2010/037243). The optical elements 20 of each row 73, 74 are aligned onto the concentrator section 71, 72 assigned respectively to them and therefore disposed obliquely and therefore tiltable according to the invention in an oblique plane indicated by the dot-dash lines 75, 76. The efficiency of the arrangement is improved by this alignment of the optical elements 20. The figure further shows a solar ray 80, a reflected ray 81 representing the first radiation path of the concentrator section 71 and a correctly running ray 82 representing the second radiation path (which therefore bypasses the limiting mirror 50). The figure further shows a preferably walk-on strip 83 as well as lateral frame parts 84 and 85 between which the concentrator sections 71, 72 are spanned. The width of the strip 83 is preferably selected so that only this is shaded by the two rows 73, 74 of optical elements 20.

In summary, it can be noted that the radiation path of a trough collector according to FIGS. 3a and 3b comprises a number of focal point regions which are disposed successively in lines, where a plurality of such lines run parallel to one another. The absorber tube is in turn disposed at the location of the focal point regions.

FIG. 4a now shows a view of a preferred embodiment of an absorber tube 20. A schematically depicted connector piece 21 for a line which removes the heat-transporting medium from the absorber tube 20 can be seen (the connector piece at the other end of the absorber tube 20 is concealed). A slit opening 22 leading over the length of the absorber tube 20 can be further seen, which opening forms the outer end of the thermal openings of the absorber tube and penetrates the outer surface 23 of the absorber tube 20.

FIG. 4b shows a view of another preferred embodiment of an absorber tube 30 that has a plurality of thermal openings 31, 32. Here there are two which corresponds to the number of concentrator sections 71, 72 of the collector 70 from FIG. 3b. However, there can also, for example, be six or more, where six corresponds to the number of concentrator sections of the embodiment shown in WO 2010/037243. The thermal openings 31, 32 extend over the length of the absorber tube 30. As mentioned above, the sum of the width of the thermal openings 31, 32 is smaller than the width of a single thermal opening (this is naturally not due to the walk-on strip 83 from FIG. 3b but also applies for a concentrator with cohesive sections).

FIG. 5a shows a cross-section through the absorber tube 20 from FIG. 4. An insulation region 25 extends from the outer surface 23 inwards and encloses a transport channel 26 for heat-transporting medium. The transport channel 26 runs through the absorber tube 20 lengthwise, is connected to the connector piece at its end and can thus convey the heat-transporting medium.

A thermal opening extending radially outwards through the insulation region 25 to the transport channel 26 passes through the insulation region and is configured here as a slit-shaped connecting channel 27. The lines 26′ and 23′ shown dashed in the figure show the course of the wall of the transport channel 26 and the course of the outer surface 23 as would exist without a connecting channel. As a result, it is apparent that the connecting channel 27 has an X-shaped contour in cross-section, having a constriction 29 at the location of the point 30 indicated in the figure. The connecting channel expands from the constriction, in the embodiment shown both towards the inside and towards the outside.

The figure further shows rays 30, 31 and 32 which represent the radiation path of the concentrator of the trough collector 1 (FIG. 1). The rays 30, 31, 32 intersect in the focal line region of the concentrator at the location of the point 30.

Thus, a thermal opening is assigned to the focal line region of the trough collector which is configured as a slit-shaped connecting channel 27 extending over the length of the absorber tube 20 between the outside world and the transport channel 26, where the constriction 29 of the thermal opening is located inside the connecting channel 27 and wherein the connecting channel 27 expands both towards the inside and towards the outside.

The configuration of the absorber tube 20 shown enables an external insulation of any thickness to be provided, for example, made of rock wool which is embedded between the transport channel 26 and the outer surface 23, which enables the absorber tube 20 to be manufactured substantially more cost-effectively compared with the absorber tubes used today. In addition, according to the invention, the unavoidably present heat-emitting surface (namely: the surface of the thermal opening, here the surface of the connecting channel 27 at its constriction) of the absorber tube 20 can be kept to a minimum which is important since the thermal irradiation increases with the fourth power of the temperature.

FIG. 5b shows a cross-section through a second preferred embodiment of an absorber tube 35 according to FIG. 4. The constriction 36 of the connecting channel 37 lies on the outer surface 23 of the absorber tube 35. The connecting channel 37 expands towards the inside and has a V-shaped cross-section.

The figure further shows rays 38 and 39 which represent the radiation path of the concentrator of the trough collector 1 (FIG. 1). The rays 38 and 39 intersect in the focal line region of the concentrator at the location of the point 40.

The embodiment shown in the figure has the aforesaid advantages of the embodiment of FIG. 5a and is also easy to manufacture.

In a further embodiment, not shown in the figures, the constriction of the connecting channel lies at the inner side of the insulation region. The connecting channel narrows to the inside, the focal region lies at the inner side of the insulation region. This is the converse configuration to the one of FIG. 5a, the connecting channel has a A-shaped cross section.

FIG. 6a shows an absorber tube 50 with a row of thermal openings 51 that is suitable for a trough collector 10 (FIG. 2a) since a thermal opening in the absorber tube 50 is then assigned to each focal point region 21 of the optical elements 20.

In the longitudinal section through the absorber tube 40 it can be seen that each thermal opening (here these are formed as V-shaped opening connecting channels 51) is separated from an adjacent thermal opening by the insulation region 25. The constriction 51 again lies on the outer surface 23 of the absorber tube 50. Rays 52, 53 here represent the second radiation path of the optical element 20 assigned to the connecting channel 51 shown (FIG. 2a).

In the transverse direction the connecting channels 51 have a configuration as shown in FIG. 5b (V-shape).

Alternatively the individual connecting channels can naturally be X-shaped in the longitudinal and in the transverse section, or can be A-shaped (constriction at the inner side of the insulation region), similar to the diagram in FIG. 5a.

FIG. 7a shows an absorber tube 100 suitable for a trough collector 60 or 70 according to FIG. 3a or 3b. The absorber tube 100 here has two rows 101, 102 of thermal openings configured as connecting channels 103. Each of the connecting channels 103 is assigned a focal point region 78 (FIG. 3a) or a focal point region of an individual optical element 20 (FIGS. 3a and 3b).

FIG. 7b shows a cross-section through the absorber tube 100 at the location of two adjacently located connecting channels 103 and 103′. Rays 105, 106 are shown which represent the second radiation path of an optical element 20 assigned to the concentrator section 71 (FIG. 3b). The rays 107, 108 on the other hand represent the second radiation path of an optical element assigned to the concentrator section 72.

Again the constrictions 110 and 11 are located on the outer surface or outer wall 23 of the absorber tube 100 and are V-shaped (or X-shaped or A-shaped) in the cross-section shown. In the longitudinal section the connecting channels preferably have the configuration of the connecting channels 51 according to FIG. 6b.

The cross-section of the absorber tube 100 from FIG. 7b corresponds to the cross-section of the absorber tube 30 from FIG. 4b, accordingly there is no special figure for the cross-section of the absorber tube 30 with the relevant reference numbers.

Preferably at least sections of the inner wall of the connecting channels are formed in such a manner that they reflect incoming concentrated radiation towards the transport channel. This is advantageous if as a result of a defective geometry in the concentrator arrangements of the trough collector or as a result of the aperture angle of the sun, radiation does not traverse the focal line or focal point region with the envisaged convergence but passes outside the focal region. Then such “defective” radiation is reflected in the transport channel 26 and not absorbed by the insulation region 25.

On the other hand, it is also possible to form the connecting channel behind the constriction as not having the complete aperture angle of the incoming radiation and to compensate for this by means of reflecting walls. Then, the focal region according to the invention also lies in the constriction so that the thermal irradiation of the concentrator through the thermal opening towards the outside is minimised.

At this point, it is noted once again that although the arrangement according to the invention of a plurality of thermal openings are described in conjunction with the constrictions according to the invention in FIGS. 4a to 7b, a plurality of thermal openings or constrictions can be achieved independently of one another, where the respective advantages then come to bear without the effect of the combination.

FIG. 8 finally shows in one diagram a comparison between the absorber tube 20 from FIG. 4a and the absorber tube 30 from FIG. 4b. A designates the width of the slit opening 22 of the absorber tube 20, B designates the width of the two slit openings 31, 32 of the absorber tube 30. The same concentrator is assigned to both absorber tubes 20, 30 where the absorber tube 20 with its slit opening 22 is disposed in the focal line region of the entire concentrator while the slit openings 30, 31 are each assigned to a half of this concentrator or to respectively one focal line region of this half.

The curves over the depicted widths A and B designate the power absorbed by the corresponding slit openings 22 or 30, 31 via the concentrated radiation.

The different in the power absorbed by an absorber tube 20 compared with an absorber tube 30 corresponds to the difference between the shaded and the two dotted areas. The dotted areas are the same size or somewhat larger than the shaded area. Consequently, the power uptake of the concentrator 30 with two less wide slit openings 31, 31 is the same size or somewhat larger than that of the concentrator 20 with only one slit opening 22.

This effect is attributable to the aperture angle of the sun whereby radiation reflected in the concentrator is necessarily scattered in a focal line region which effect is increased with increasing distance of the edge zones of the concentrator.

In summary, the efficiency of the absorber tube and therefore of the collector according to the invention can be improved in three steps:

On the one hand the thermal opening (or the open cross-sectional area of the connecting channel 27 with respect to the transport channel 26) is minimised to a constriction which is reduced to the dimension of the focal line region of conventional trough concentrators.

The thermal opening is then resolved into a number of smaller thermal openings with a total area of the smaller openings which is smaller than the area of the single thermal opening. This is made possible by using a second concentrator arrangement which resolves the focal line region of the trough concentrator into focal point regions.

Finally, the conventional thermal opening running over the length of the absorber tube is resolved into thermal openings having a smaller width and each of the less wide thermal openings is assigned to a concentrator section. At the same time, the same heat input into the absorber tube as is the case with a single thermal opening is accomplished with smaller total area of the thermal openings. In addition these thermal openings can be provided with a constriction.

1. A trough collector comprising a focal region and an absorber tube disposed in the focal region, which has an insulation region extending inwards from its outer surface, which surrounds a transport channel for heat-transporting medium running lengthwise through the absorber tube and which is penetrated by at least one thermal opening extending radially from outside through the insulation region to the transport channel, wherein the at least one thermal opening for radiation passing through has a constriction and wherein the focal region lies in the constriction.

2. The trough collector according to claim 1, wherein the thermal opening expands after the constriction continuously inwards in such a manner that substantially the entire radiation entering into the thermal opening and diverging again after the focal region can directly reach the transport channel.

3. The trough collector according to claim 1, wherein the thermal opening is formed as a connecting channel extending from the outer surface of the absorber tube into the transport channel, wherein the connecting channel expands continuously inwards behind the constriction and is preferably configured with reflecting walls in such a manner that the radiation diverging again after the focal region completely reaches the transport channel substantially without absorption at the reflecting walls.

4. The trough collector according to claim 1, comprising one or more focal line regions, wherein each focal line region is assigned a thermal opening which is configured as a slit-shaped connecting channel extending over the length of the absorber tube between the outside world and the transport channel, wherein the constriction of each thermal opening preferably lies on the outer surface of the absorber tube and wherein the connecting channel expands towards the inside.

5. The trough collector according to claim 1, comprising one or more focal line regions, wherein each focal line region is assigned at least one thermal opening which is configured as a slit-shaped connecting channel extending over the length of the absorber tube between the outside world and the transport channel, wherein the constriction of each thermal opening is located inside the connecting channel such that the connecting channel expands both towards the inside and towards the outside or the constriction of each thermal opening is located at the inside of the insulation region.

6. A trough collector according to claim 1 having a plurality of rows of focal point regions lying adjacent to each other, wherein each focal point is assigned a single thermal opening configured as a connecting channel which is separated from the other thermal openings by the insulation region, whose constriction preferably lies on the outer surface of the absorber tube.

7. A trough collector according to claim 1 having a plurality of rows of focal point regions lying adjacent to each other wherein each focal point is assigned a single thermal opening configured as a connecting channel which is separated from the other thermal openings by the insulation region, whose constriction lies inside the connecting channel and wherein the connecting channel expands out from this both towards the inside and towards the outside or whose constriction lies at the inside of the insulation region.

8. The trough collector according to claim 1, wherein at least sections of the inner wall of the connecting channel are configured in such a manner that they reflect incoming concentrated radiation towards the transport channel.

9. An absorber tube for a trough collector which has an insulation region extending inwards from its outer surface, which surrounds a transport channel for heat-transporting medium running lengthwise through the absorber tube and which is penetrated by at least one thermal opening extending radially from outside through the insulation region to the transport channel, wherein the at least one thermal opening for radiation passing through has a constriction and expands from this.

10. The absorber tube according to claim 9, wherein the at least one thermal opening is configured as a slit-shaped connecting channel which extends over the length of the absorber tube, wherein its constriction is located on the outer surface of the absorber tube.

11. The absorber tube according to claim 9, wherein the at least one thermal opening is configured as a slit-shaped connecting channel which extends over the length of the absorber tube, wherein its constriction is located in its interior and wherein the connecting channel expands from this both towards the inside and towards the outside.

12. The absorber tube according to claim 9, wherein a number of thermal openings disposed successively in a row over the length of the absorber tube are provided, which are separated by an insulation region.

13. The absorber tube according to claim 9, wherein several rows of thermal openings are provided parallel to one another.

14. The absorber tube according to claim 9, wherein each thermal opening is configured as a connecting channel which extends from the outer surface towards the inside, whose constriction lies on the outer surface and which expands inwards.

15. The absorber tube according to claim 9, wherein each thermal opening is configured as a connecting channel which extends from the outer surface towards the inside, whose constriction is located in its interior and the connecting channel expands from this both towards the inside and towards the outside.

16. The absorber tube according to claim 9, wherein at least sections of the inner wall of the connecting channels are configured in such a manner that they reflect incoming concentrated radiation towards the transport channel.

17. The absorber tube according to claim 16, wherein the reflecting sections are configured as compound parabolic concentrators.

18. A trough collector having a linear concentrator which is divided into several sections running parallel to one another, characterised by an absorber tube which has an insulation region extending inwards from its outer surface, which surrounds a transport channel for heat-transporting medium running lengthwise and for each of the sections of the linear concentrator has at least one thermal opening, wherein this at least one opening per section run parallel adjacent to one another and extend over the length of the absorber tube or wherein for each of the sections a row of consecutively arranged thermal openings is provided.

19. The trough collector according to claim 18, wherein the thermal openings are configured as connecting channels extending from the outer surface of the absorber tube into the transport channel and wherein the connecting channels are separated from one another by the insulation region.

20. An absorber tube for a trough collector which has an insulation region extending inwards from its outer surface, which surrounds a transport channel for heat-transporting medium running lengthwise characterised by a plurality of thermal openings running parallel to one another and extending over the length of the absorber tube or by a plurality of rows extending over the length of the absorber tube, each row formed of consecutively arranged thermal openings.

21. The absorber tube according to claim 17, wherein the thermal openings are configured as connecting channels extending from the outer surface of the absorber tube into the transport channel and wherein the connecting channels are separated from one another by the insulation region.

22. The absorber tube according to claim 17, wherein two, preferably four, and particularly preferably six thermal openings or rows of thermal openings are provided.

23. The trough collector according to claim 1, whereby the thermal openings are formed as mounts for photovoltaic cells.
